(19) United States
(12) Patent Application Publication
(10) Pub. No.: US 2023/0274954 A1
(43) Pub. Date: Aug. 31, 2023

(54) SUBSTRATE SUPPORTS WITH MULTILAYER STRUCTURE INCLUDING COUPLED HEATER ZONES WITH LOCAL THERMAL CONTROL

(71) Applicant: LAM RESEARCH CORPORATION, Fremont, CA (US)

(72) Inventors: Harmeet SINGH, Fremont, CA (US); Slobodan MITROVIC, Union City, CA (US); Darrell EHRLICH, San Jose, CA (US); Benny WU, Fremont, CA (US)

(21) Appl. No.: 18/013,445

(22) PCT Filed: Aug. 2, 2021
(86) PCT No.: PCT/US2021/044122

§ 371 Date: Dec. 28, 2022

Related U.S. Application Data
(60) Provisional application No. 63/063,700, filed on Aug. 10, 2020.

(51) Int. Cl. H01L 21/67; H05B 3/28

(52) U.S. Cl. CPC H01L 21/67103; H01L 21/67248; H05B 3/283

(57) ABSTRACT

A substrate support assembly for supporting a substrate includes a baseplate, a ceramic plate arranged on the baseplate, and N resistive heaters arranged in X rows and Y columns and coupled to the ceramic plate. X, Y, and N are integers greater than 1, and N is less than or equal to X*Y. Each of the N resistive heaters have a first terminal and a second terminal. The ceramic plate includes Y conductors arranged in a first layer of the ceramic plate, and X conductors arranged in a second layer of the ceramic plate. The first terminals of each resistive heater in one of the X rows are directly connected to the Y conductors, respectively, by first vias. Second terminals of each resistive heater in the one of the X rows are directly connected to one of the X conductors by second vias.

### CROSS-REFERENCE TO RELATED APPLICATIONS

This application claims the benefit of U.S. Provisional Application No. 63/063,700, filed on Aug. 10, 2020. The entire disclosure of the application referenced above is incorporated herein by reference.

### FIELD

The present disclosure relates generally to substrate processing systems and more particularly to substrate supports with multilayer structure including coupled heater zones with local thermal control.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes several processing chambers (also called process modules) to perform deposition, etching, and other treatments of substrates such as semiconductor wafers. Examples of processes that may be performed on a substrate include, but are not limited to, plasma enhanced chemical vapor deposition (PECVD), chemically enhanced plasma vapor deposition (CEPVD), sputtering physical vapor deposition (PVD), atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support assembly such as a pedestal or an electrostatic chuck (ESC) arranged in a processing chamber of the substrate processing system. A robot typically transfers substrates from one processing chamber to another in a sequence in which the substrates are to be processed. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. The processing chambers are periodically cleaned by supplying a cleaning gas into the processing chamber and striking plasma.

### SUMMARY

A substrate support assembly for supporting a substrate comprises a baseplate, a ceramic plate arranged on the baseplate, and N resistive heaters arranged in X rows and Y columns and coupled to the ceramic plate. X, Y, and N are integers greater than 1, and N is less than or equal to X*Y. Each of the N resistive heaters have a first terminal and a second terminal. The ceramic plate includes Y conductors arranged in a first layer of the ceramic plate, and X conductors arranged in a second layer of the ceramic plate. The first terminals of each resistive heater in one of the X rows are directly connected to the Y conductors, respectively, by first vias. Second terminals of each resistive heater in the one of the X rows are directly connected to one of the X conductors by second vias.

In another feature, the N resistive heaters are electrically insulated from the baseplate and are arranged at the bottom of the ceramic plate between the baseplate and the ceramic plate.

In another feature, the N resistive heaters are arranged in a third layer of the ceramic plate.

In another feature, the substrate support assembly further comprises a controller configured to connect one of the Y conductors to a power supply, and to connect one of the X conductors to a reference potential.

In another feature, the substrate support assembly further comprises a controller configured to connect the Y conductors to a power supply and the X conductors to a reference potential in a sequence by connecting one of the Y conductors to the power supply and connecting one of the X conductors to the reference potential at a time.

In another feature, the sequence is based on a temperature profile for processing the substrate.

In another feature, the substrate support assembly further comprises a controller configured to connect a first one of the Y conductors to a power supply for a first time period, to connect a first one of the X conductors to a reference potential for the first time period, to disconnect the first one of the Y conductors from the power supply after the first time period, and to connect a second one of the Y conductors to the power supply for a second time period.

In another feature, the substrate support assembly further comprises a controller configured to connect a first one of the Y conductors to a power supply for a first time period, to connect a first one of the X conductors to a reference potential for the first time period, to disconnect the first one of the X conductors from the reference potential after the first time period, and to connect a second one of the X conductors to the reference potential for a second time period.

In another feature, the substrate support assembly further comprises a controller configured to connect a first one of the Y conductors to a power supply for a first time period, to connect a first one of the X conductors to a reference potential for the first time period, to disconnect the first one of the Y conductors from the power supply after the first time period, to disconnect the first one of the X conductors from the reference potential after the first time period, to connect a second one of the Y conductors to the power supply for a second time period, and to connect a second one of the X conductors to the reference potential for the second time period.

In another feature, the second layer is adjacent to the baseplate, and the first layer is arranged on the second layer.

In another feature, the second layer is adjacent to the baseplate, the first layer is arranged on the second layer, and the third layer is arranged on the first layer.

In another feature, the first, second, and third layers are arranged in any order.

In another feature, the substrate support assembly further comprises one or more additional heaters arranged in a third layer of the ceramic plate. The third layer is arranged above or below the first and second layers.

In another feature, the substrate support assembly further comprises one or more additional heaters arranged in a fourth layer of the ceramic plate. The fourth layer is arranged above or below the first, second, and third layers.

In another feature, the substrate support assembly further comprises a clamping electrode and one or more additional heaters arranged in a third layer of the ceramic plate. The third layer is arranged above the first and second layers.

In other features, the substrate support assembly further comprises a clamping electrode arranged in a third layer of the ceramic plate. The third layer is arranged above the first and second layers. The substrate support assembly further comprises one or more additional heaters arranged in a fourth layer of the ceramic plate. The fourth layer is arranged below the first and second layers.

In another features, the substrate support assembly further comprises a clamping electrode and one or more additional heaters arranged in a fourth layer of the ceramic plate. The fourth layer is arranged above the first, second, and third layers.

In other features, the substrate support assembly further comprises a clamping electrode arranged in a fourth layer of the ceramic plate. The fourth layer is arranged above the first, second, and third layers. The substrate support assembly further comprises one or more additional heaters arranged in a fifth layer of the ceramic plate. The fifth layer is arranged below the first, second, and third layers.

In another feature, the substrate support assembly further comprises an adhesive layer arranged between the baseplate and the ceramic plate.

In another feature, the baseplate includes channels for flowing a coolant through the baseplate.

In other features, a system comprises the substrate support assembly, a power supply configured to supply a first DC voltage, and a controller. The controller is configured to sequentially apply the first DC voltage across the X and Y conductors by connecting one pair of the X and Y conductors at a time to the power supply and a reference potential.

In another feature, a sequence for sequentially applying the first DC voltage across the X and Y conductors is based on a temperature profile for processing the substrate.

In other features, the substrate support assembly further comprises one or more additional heaters arranged in a third layer of the ceramic plate, wherein the third layer is arranged above or below the first and second layers. The power supply is configured to supply a second DC voltage. The controller is configured to supply the second DC voltage to the one or more additional heaters.

In other features, a system comprises the substrate support assembly, a power supply configured to supply a first DC voltage, and a controller. The controller is configured to sequentially apply the first DC voltage across the X and Y conductors by connecting one pair of the X and Y conductors at a time to the power supply and a reference potential.

In another feature, a sequence for sequentially applying the first DC voltage across the X and Y conductors is based on a temperature profile for processing the substrate.

In other features, the substrate support assembly further comprises one or more additional heaters arranged in a fourth layer of the ceramic plate. The fourth layer is arranged above or below the first, second, and third layers. The power supply is configured to supply a second DC voltage. The controller is configured to supply the second DC voltage to the one or more additional heaters.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows a first example of a substrate processing system according to the present disclosure;

FIG. 1B shows a second example of a substrate processing system according to the present disclosure;

FIG. 2A shows an example of a heater array including switches used in substrate support subsystems;

FIG. 2B shows a cross-sectional view of a substrate support subsystem including the heater array and switches of FIG. 2A;

FIG. 3A shows an example of a heater array without switches according to the present disclosure;

FIG. 3B shows a cross-sectional view of a substrate support including the heater array of FIG. 3A;

FIG. 4 shows the substrate support of FIG. 3B further comprising a zone heater;

FIG. 5 shows an example of a controller to control the heater array of FIG. 3A;

FIG. 6A shows an example of the heater array of FIG. 3A with a first pair of X and Y bus lines connected to a reference potential and a power supply, respectively;

FIGS. 6B, 6C, and 6D show some of a number of examples of various current paths through different heaters of the heater array of FIG. 3A when power is supplied to the heater array as shown in FIG. 6A;

FIG. 6E shows an example of relative power dissipated by the heaters of the heater array of FIG. 3A when power is supplied to the heater array as shown in FIG. 6A;

FIG. 7A shows the heater array of FIG. 3A with a second pair of X and Y bus lines connected to the reference potential and the power supply, respectively;

FIG. 7B shows an example of heat generated by the heaters of the heater array of FIG. 3A when power is supplied to the heater array as shown in FIG. 7A;

FIG. 8A shows another example of a heater array without switches according to the present disclosure;

FIG. 8B shows an example of heat generated by the heaters of the heater array of FIG. 8A when power is supplied to the heater array as shown in FIG. 8A; and

FIG. 9 shows a method of controlling a heater array according to the present disclosure.

In the drawings, reference numbers may be reused to identify similar and/or identical elements.

### DETAILED DESCRIPTION

Substrate supports include heaters to heat substrates during processing. The heaters are controlled to maintain desired temperature profiles across the substrates. Some substrate supports include an array of heaters (e.g., resistive heaters) and switches (e.g., diodes). The heaters in the array are independently operated by controlling the switches. While one of the heaters in the array is turned on and emits heat, all other heaters in the array that are not selected are turned off and do not emit heat. While such a heater array provides a more localized heat output, the heater array uses one switch (e.g., diode) for every heater in the heater array to provide the ability to independently control each heater in the heater array. The switches increase manufacturing complexity, add cost, and have reliability and lifetime issues.

The present disclosure provides a heater array without switches. The substrate support according to the present disclosure includes only resistive traces as heaters, bus lines connected directly to the heaters, and wired connections to a controller connected to a power source that supplies power to the heaters in the heater array. No switches or switch interconnects for the heaters are needed in the heater array.

More specifically, the heater array according to the present disclosure includes resistive heaters (hereinafter heaters) arranged along X rows of conductors (called X conductors or X bus lines) and Y columns of conductors (called Y conductors or Y bus lines). Every heater in a row is directly connected to a conductor in a row (an X bus line), and every heater in a column is directly connected to a conductor in a column (a Y bus line). The X and Y bus lines do not intersect each other. A selected one of the conductors in the columns (i.e., a Y bus line) is connected to a power supply, and a selected one of the conductors in the rows (i.e., an X bus line) is connected to a reference potential (e.g., ground). Conversely, in some implementations, power is selectively supplied to the X bus lines, and the Y bus lines are selectively grounded.

In the heater array, the highest amount of heat is generated by the heater that is connected to both the selected column and the selected row, which are respectively connected to the power supply and ground. A relatively smaller amount of heat is generated by every other heater on the selected column and the selected row. A still smaller amount of heat is generated by the rest of the heaters in the heater array. Although only one X bus line and only one Y bus line is selected at a time, graded heat is generated throughout the heater array since various current paths are available in the heater array because of the direct connections of the heaters to the X and Y bus lines. Heat patterns generated by selecting different combinations of heaters can be used to create a global heating response with localized control of temperature.

Due to the direct connections of the heaters to the rows and columns of the heater array, the heater array eliminates the need for switches (e.g., diodes), which increases reliability of operation and lifetime, and reduces complexity and cost of manufacturing substrate supports. While a completely localized heater response, which is possible when switches are used, is unavailable, a relatively localized temperature response is achieved due to the coupling between the selected and unselected heaters. These and other features of the present disclosure are described below in detail.

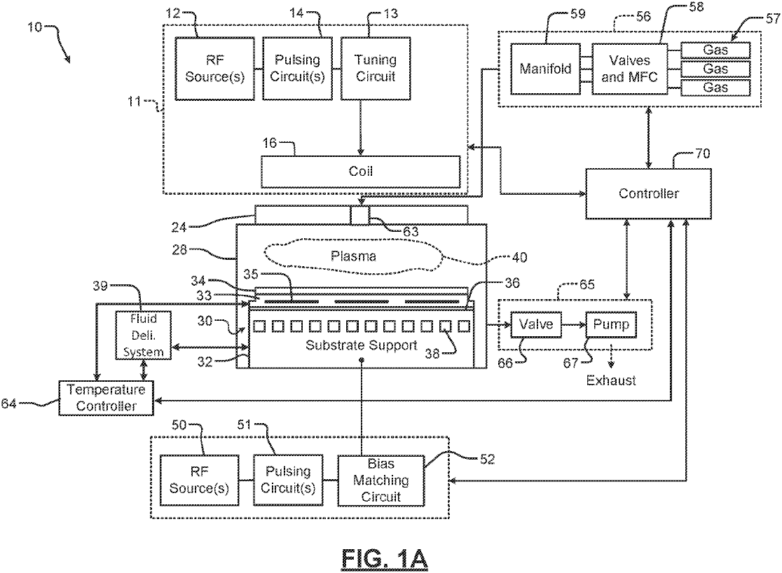

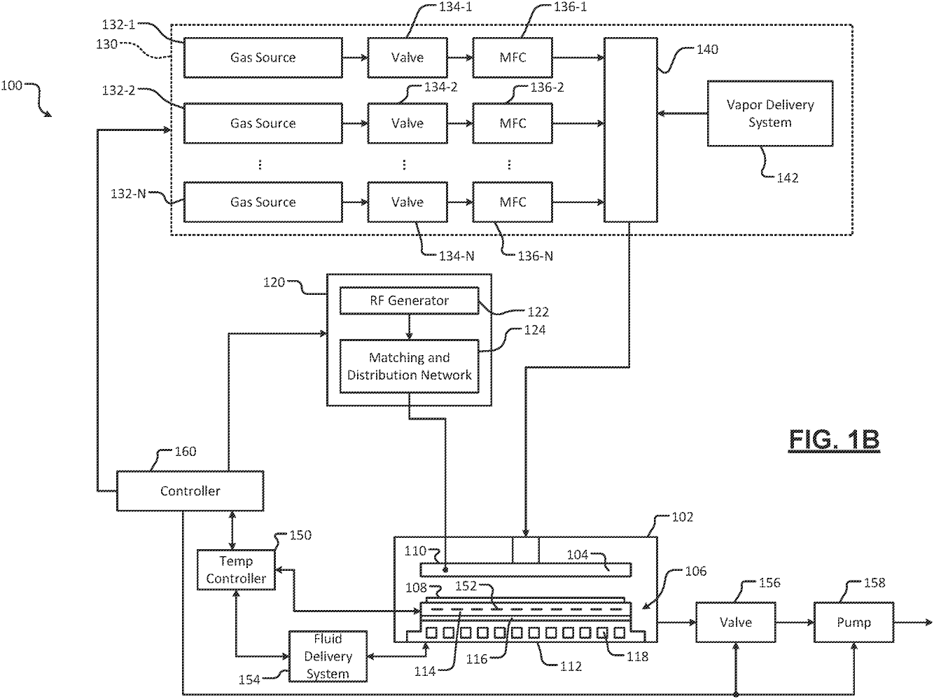

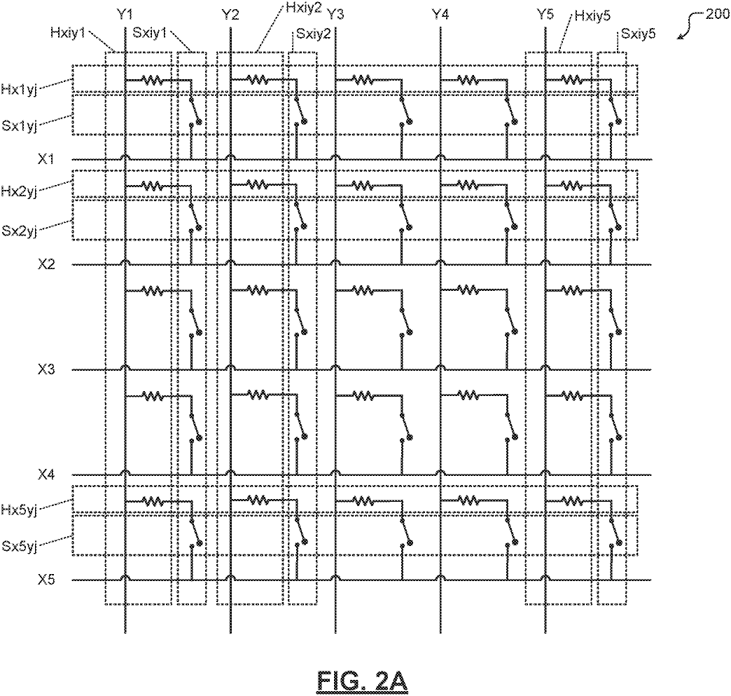

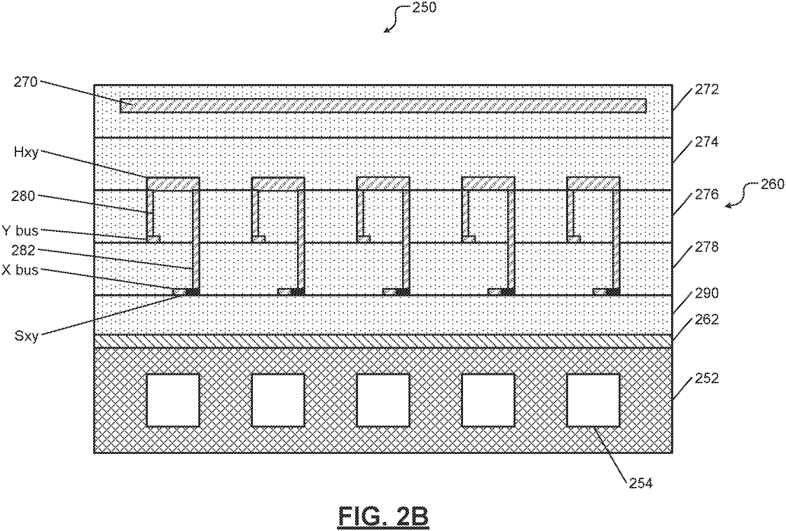

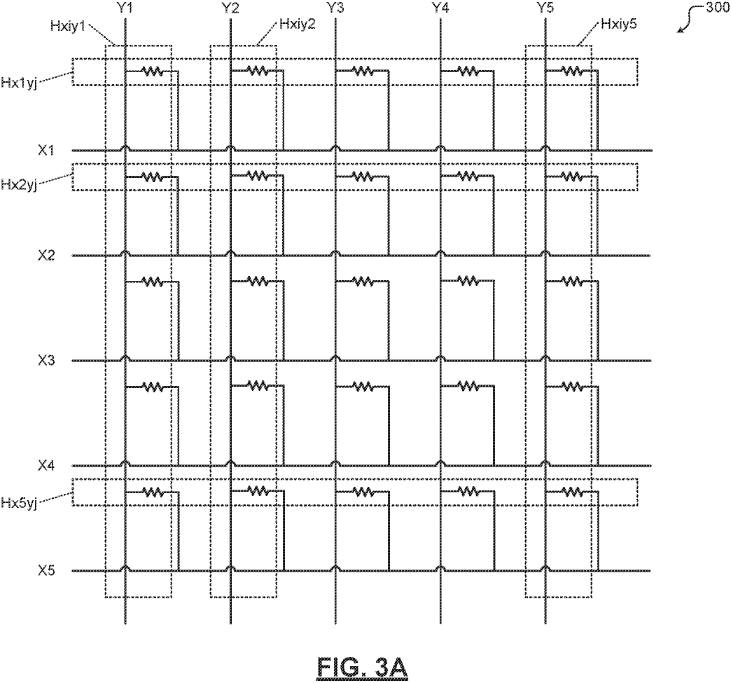

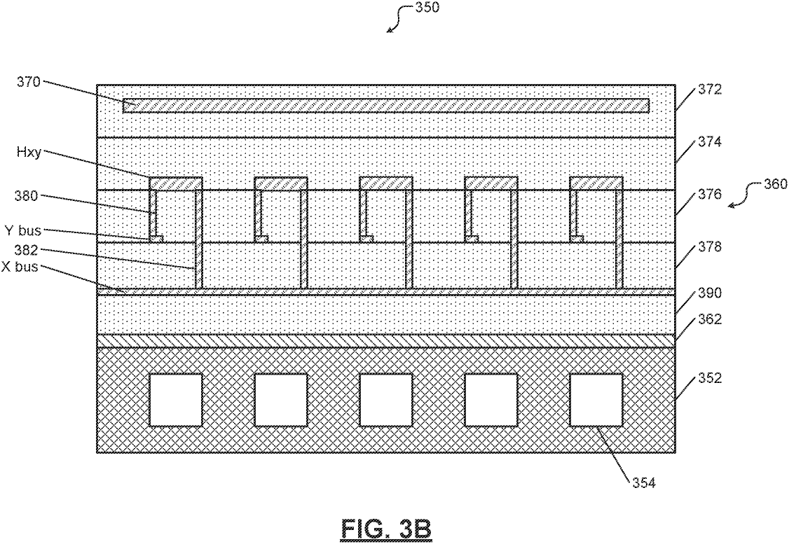

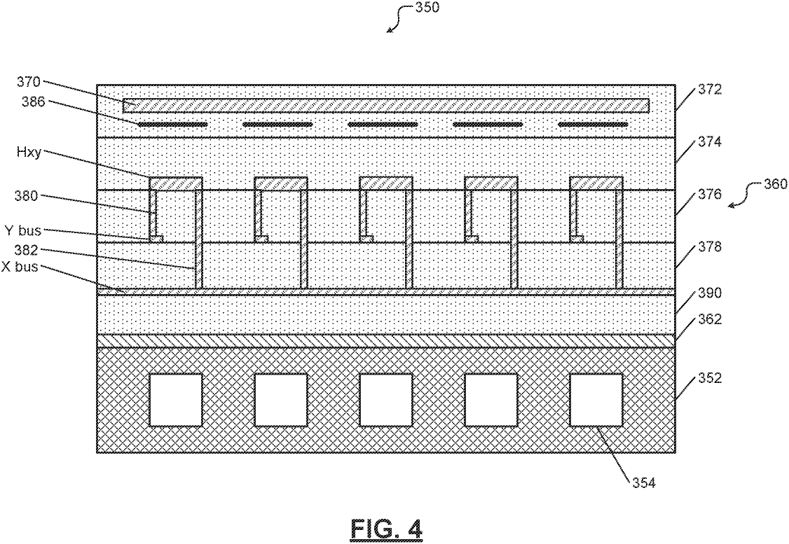

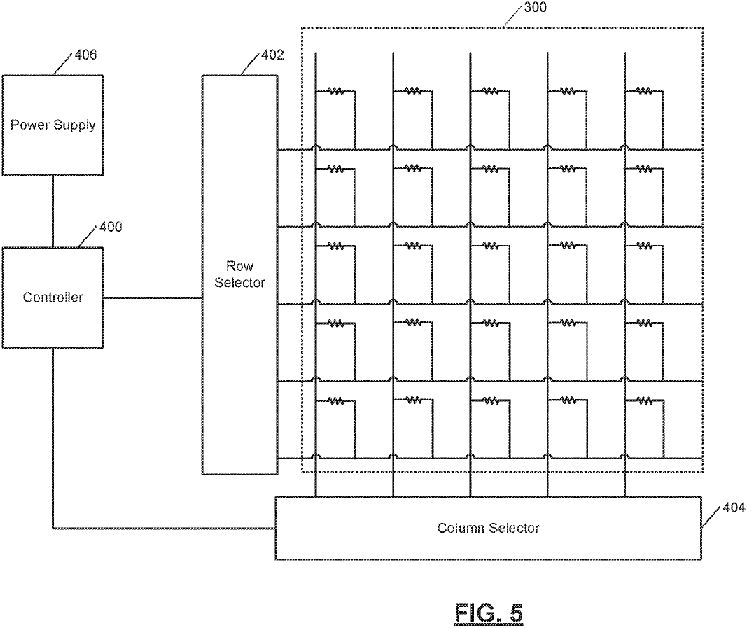

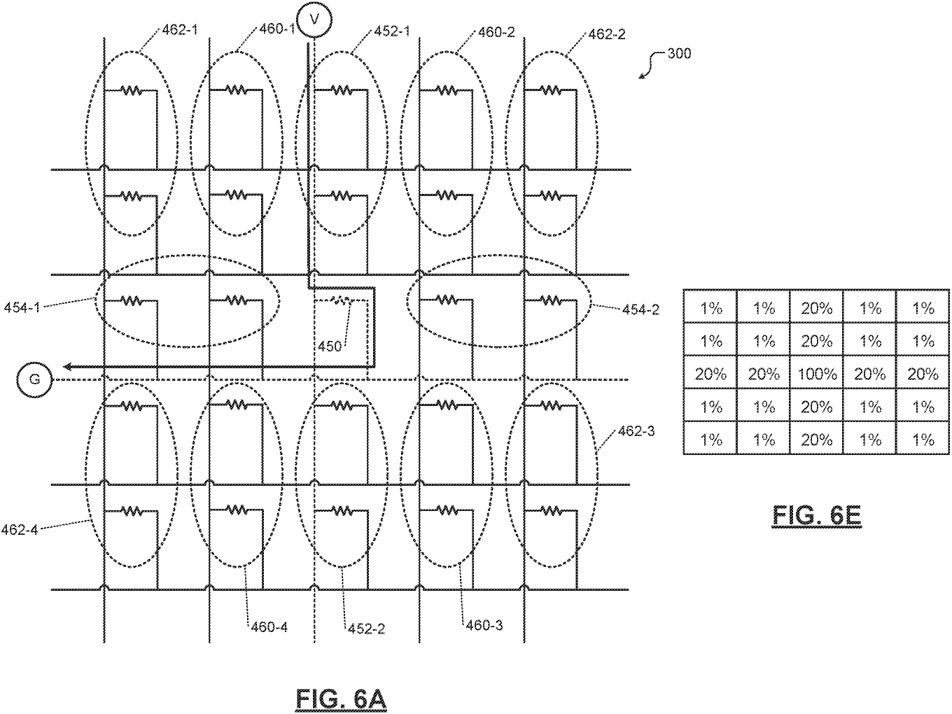

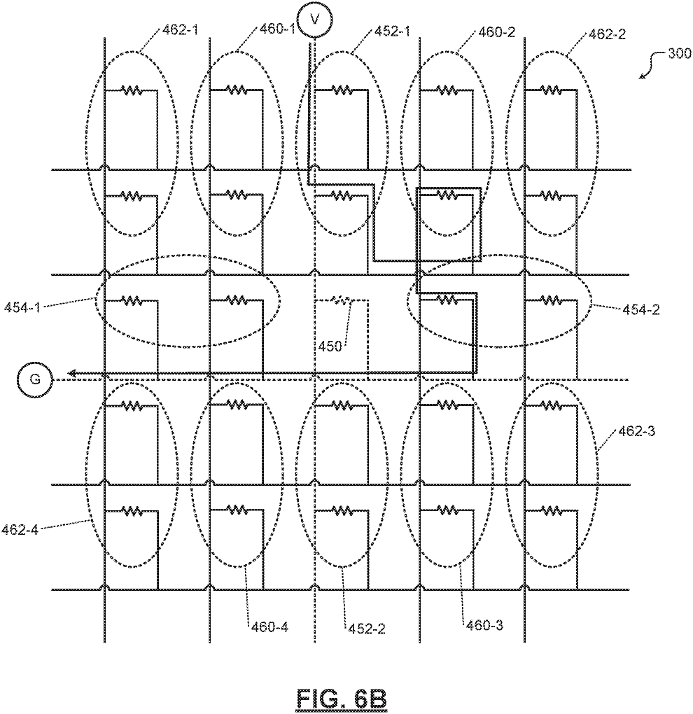

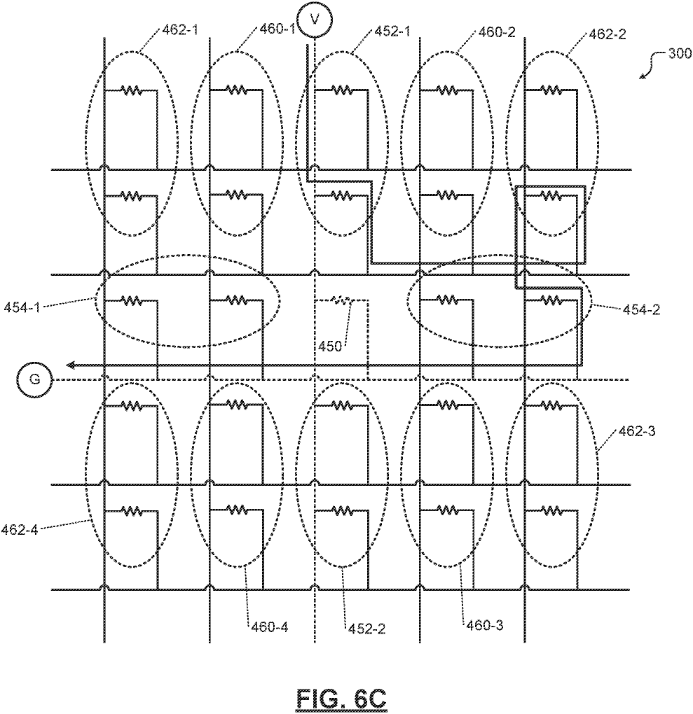

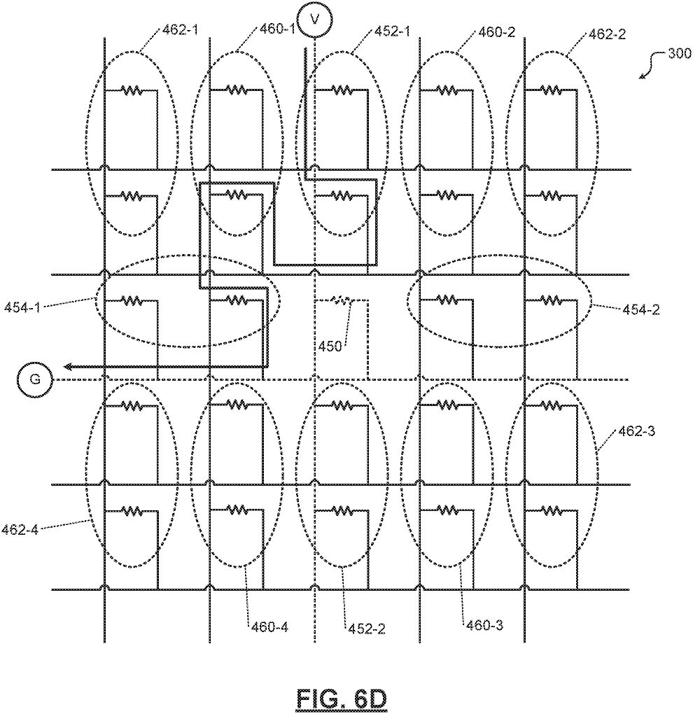

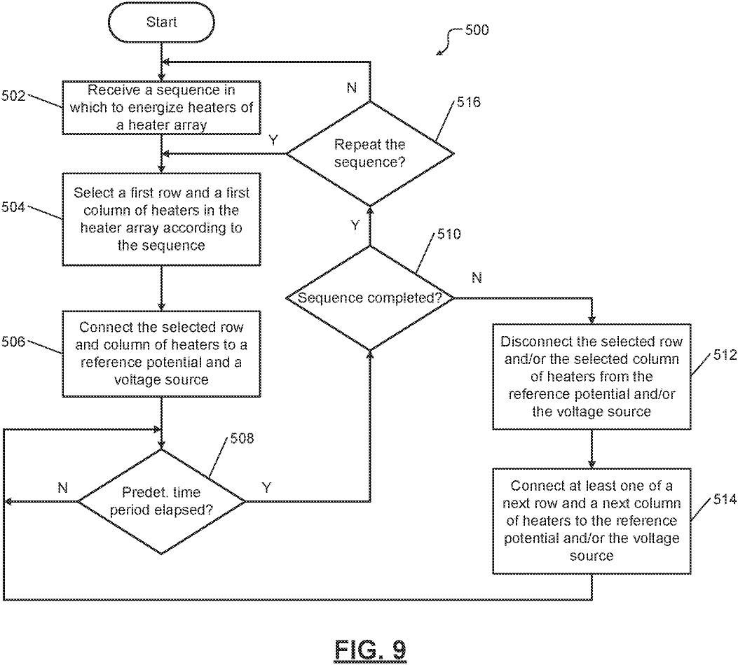

The present disclosure is organized as follows. Initially, examples of substrate processing systems in which the heater array of the present disclosure can be used are shown and described with reference to FIGS. 1A and 1B. Thereafter, an example of a heater array including switches is shown and described with reference to FIGS. 2A and 2B. An example of a heater array without switches according to the present disclosure is shown and described with reference to FIGS. 3A-3B. An example of a substrate support including the heater array without switches and including an additional zone heater is shown and described with reference to FIG. 4. An example of a controller to control the heater array is shown and described with reference to FIG. 5. Examples of various configurations of the heater array are shown and described with reference to FIGS. 6A-8B. A method of controlling a heater array is shown and described with reference to FIG. 9.

FIG. 1A shows an example of a substrate processing system 10 that uses inductively coupled plasma to etch substrates such as semiconductor wafers according to the present disclosure. The substrate processing system 10 includes a coil driving circuit 11. In some examples, the coil driving circuit 11 includes an RF source 12, a pulsing circuit 14, and a tuning circuit (i.e., matching circuit) 13. The pulsing circuit 14 controls a transformer coupled plasma (TCP) envelope of an RF signal generated by the RF source 12 and varies a duty cycle of TCP envelope between 1% and 99% during operation. The pulsing circuit 14 and the RF source 12 can be combined or separate.

The tuning circuit 13 may be directly connected to an inductive coil 16. While the substrate processing system 10 uses a single coil, some substrate processing systems may use a plurality of coils (e.g., inner and outer coils). The tuning circuit 13 tunes an output of the RF source 12 to a desired frequency and/or a desired phase, and matches an impedance of the inductive coil 16.

A dielectric window 24 is arranged along a top side of a processing chamber 28. The processing chamber 28 comprises a substrate support (or pedestal) 30 to support a substrate 34. The substrate support 30 may include an electrostatic chuck (ESC), or a mechanical chuck or other type of chuck. The substrate support 30 comprises a baseplate 32. A ceramic plate 33 is arranged on a top surface of the baseplate 32. A thermal resistance layer 36 may be arranged between the ceramic plate 33 and the baseplate 32. The substrate 34 is arranged on the ceramic plate 33 during processing.

A heater array 35 including a plurality of heaters according to the present disclosure is arranged in the ceramic plate 33 to heat the substrate 34 during processing. For example, the heater array 35 comprises printed resistive traces embedded in the ceramic plate 33 as explained below in detail with reference to FIGS. 3A and 3B. An additional heater (not shown) may be arranged above or below the heater array 35 as explained below with reference to FIG. 4.

The baseplate 32 further includes a cooling system 38 to cool the substrate support 30. The cooling system 38 uses a fluid supplied by a fluid delivery system 39 to cool the substrate support 30. For example, the cooling system 38 comprises cooling channels through which the fluid from the fluid delivery system 39 is flowed to cool the substrate support 30.

A process gas is supplied to the processing chamber 28, and plasma 40 is generated in the processing chamber 28. The plasma 40 etches an exposed surface of the substrate 34. An RF source 50, a pulsing circuit 51, and a bias matching circuit 52 may be used to bias the substrate support 30 during processing to control ion energy.

A gas delivery system 56 may be used to supply a process gas mixture to the processing chamber 28. The gas delivery system 56 may include process and inert gas sources 57, a gas metering system 58 such as valves and mass flow controllers, and a manifold 59. A gas injector 63 may be arranged at a center of the dielectric window 24 and is used to inject gas mixtures from the gas delivery system 56 into the processing chamber 28. Additionally or alternatively, the gas mixtures may be injected from the side of the processing chamber 28.

A temperature controller 64 may be connected to the heater array 35 and may be used to control the heater array 35 to control a temperature of the substrate support 30 and the substrate 34. The temperature controller 64 controls the heater array 35 as described below in detail with reference to FIGS. 3A and 3B. The temperature controller 64 may communicate with the fluid delivery system 39 to control fluid flow through the cooling system 38 to cool the substrate support 30.

An exhaust system 65 includes a valve 66 and pump 67 to control pressure in the processing chamber 28 and/or to remove reactants from the processing chamber 28 by purging or evacuation. A controller 70 may be used to control the etching process. The controller 70 controls the components of the substrate processing system 10. The controller 70 monitors system parameters and controls delivery of the gas mixture; striking, maintaining, and extinguishing the plasma; removal of reactants; supply of cooling fluid; and so on. Additionally, the controller 70 may control various aspects of the coil driving circuit 11, the RF source 50, and the bias matching circuit 52, and so on.

FIG. 1B shows another example of a substrate processing system 100 comprising a processing chamber 102 configured to generate capacitively coupled plasma. While the example is described in the context of plasma enhanced chemical vapor deposition (PECVD), the teachings of the present disclosure can be applied to other types of substrate processing such as atomic layer deposition (ALD), plasma enhanced ALD (PEALD), CVD, or also other processing including etching.

The substrate processing system 100 comprises the processing chamber 102 that encloses other components of the substrate processing system 100 and contains RF plasma (if used). The processing chamber 102 comprises an upper electrode 104 and an electrostatic chuck (ESC) 106 or other type of substrate support. During operation, a substrate 108 is arranged on the ESC 106.

For example, the upper electrode 104 may include a gas distribution device 110 such as a showerhead that introduces and distributes process gases into the processing chamber 102. The gas distribution device 110 may include a stem portion including one end connected to a top surface of the processing chamber 102. A base portion of the showerhead is generally cylindrical and extends radially outwardly from an opposite end of the stem portion at a location that is spaced from the top surface of the processing chamber 102. A substrate-facing surface or faceplate of the base portion of the showerhead includes a plurality of outlets or features (e.g., slots or through holes) through which vaporized precursor, process gas, cleaning gas, or purge gas flows.

The ESC 106 comprises a baseplate 112 that acts as a lower electrode. A ceramic plate 114 is arranged on a top surface of the baseplate 112. A thermal resistance layer 116 may be arranged between the ceramic plate 114 and the baseplate 112. The ceramic plate 114 includes a heater array 152 according to the present disclosure to heat the substrate 108. The heater array 152 comprises printed resistive traces embedded in the ceramic plate 114 as explained below in detail with reference to FIGS. 3A and 3B. An additional heater (not shown) may be arranged above or below the heater array 152 as explained below with reference to FIG. 4.

The baseplate 112 further includes a cooling system 118 to cool the ESC 106. The cooling system 118 uses a fluid supplied by a fluid delivery system 154 to cool the ESC 106. For example, the cooling system 118 comprises cooling channels through which the fluid from the fluid delivery system 154 is flowed to cool the ESC 106.

If plasma is used, an RF generating system (or an RF source) 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example, the RF generating system 120 may include an RF generator 122 that generates RF power that is fed by a matching and distribution network 124 to the upper electrode 104 or the baseplate 112. In other examples, while not shown, the plasma may be generated inductively or remotely and then supplied to the processing chamber 102.

A gas delivery system 130 includes one or more gas sources 132-1, 132-2, ..., and 132-N (collectively gas sources 132), where N is an integer greater than zero. The gas sources 132 are connected by valves 134-1, 134-2, ..., and 134-N (collectively valves 134) and mass flow controllers 136-1, 136-2, ..., and 136-N (collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102. The gas sources 132 may supply process gases, cleaning gases, or purge gases.

A temperature controller 150 may be connected to the heater array 152 and may be used to control the heater array 152 to control a temperature of the ESC 106 and the substrate 108. The temperature controller 150 controls the heater array 152 as described below in detail with reference to FIGS. 3A and 3B. The temperature controller 150 may communicate with the fluid delivery system 154 to control fluid flow through the cooling system 118 to cool the ESC 106.

A valve 156 and pump 158 may be used to evacuate reactants from the processing chamber 102. A system controller 160 controls the components of the substrate processing system 100.

FIG. 2A shows a heater array 200 including a plurality of heaters (resistive elements) arranged in a substrate support (e.g., elements 30 and 106 shown in FIGS. 1A and 1B). For example, the heater array 200 comprises five Y bus lines (Y1, Y2, Y3, Y4, and Y5) and five X bus lines (X1, X2, X3, X4, and X5) arranged in the form of a grid in a ceramic plate (e.g., elements 33 and 114 shown in FIGS. 1A and 1B) of the substrate support. Note that while FIG. 2A shows X=Y, X need not be equal to Y, and X and Y can be any integer greater than 1. Alternatively, the heater array 200 can be arranged elsewhere in the substrate support (e.g., under or at the bottom of the ceramic plate and so on).

In the embodiment depicted in FIG. 2A, the heater array 200 comprises X*Y (i.e., X multiplied by Y) number of heaters. Each heater in the heater array 200 can be identified by its location along the X and Y bus lines as a heater Hxy, where x and y respectively denote one of the X bus lines and one of the Y bus lines to which the heater Hxy is connected. In some embodiments, the heater array 200 can include less than X*Y number of heaters (i.e., one or more of the heaters Hxy may be absent in the heater array 200). For example, in each row X, the number of heating elements may be less than or equal to Y. Similarly, each row Y may have a number of heating elements that is less than or equal to X.

The heater array 200 includes Y sets of heaters Hxiy1, Hxiy2, and so on that are arranged along Y columns of the heater array 200, where i = 1 to 5; and X sets of heaters Hx1yj, Hx2yj, and so on that are arranged along X rows of the heater array 200, where j=1 to 5. Each of the Y sets of heaters is connected to one of the Y bus lines of the heater array 200. Each of the X sets of heaters is connected to one of the X bus lines of the heater array 300. Specifically, heaters in a column have first terminals connected to the Y bus line in the column and second terminals connected to respective X bus lines in the X rows, and heaters in a row have first terminals connected to respective Y bus lines in the Y columns and second terminals connected the X bus line in the row.

For example, in the Y sets of heaters, the heaters Hxiy1, where i = 1 to 5, have first terminals directly connected to the Y1 bus line and second terminals connected to respective X bus lines via respective switches Sxiy1, where i = 1 to 5; the heaters Hxiy2, where i = 1 to 5, have first terminals directly connected to the Y2 bus lines and second terminals connected to respective X bus lines via respective switches Sxiy2, where i = 1 to 5; and so on.

In the X sets of heaters, the heaters Hx1yj, where j = 1 to 5, have first terminals directly connected to respective Y bus lines and second terminals connected to the X1 bus line via respective switches Sx1yj, where j = 1 to 5; the heaters Hx2yj, have first terminals directly connected to respective Y bus lines and second terminals connected to the X2 bus line via respective switches Sx2yj, where j = 1 to 5; and so on.

The switches Sxiy1, Sxiy2, and so on and the switches Sx1yj, Sx2yj, and so on are collectively called switches Sxy. The number of switches Sxy is equal to the number of heaters Hxy, which is X*Y (i.e., X multiplied by Y).

The Y and X bus lines are respectively connected to a power supply (e.g., a voltage source) and a reference potential (e.g., ground). A controller (e.g., element 64 or 150 shown in FIGS. 1A and 1B) controls the switches Sxy. The controller selects and turns on only one switch at a time to connect only one of the heaters to the power supply and ground. All other switches are not selected, and the respective heaters are not turned on. Accordingly, the controller operates each heater in the heater array 200 individually and independently of the other heaters in the heater array 200. In some implementations, the controller can select and turn on any number of the switches Sxy simultaneously along one Y-bus.

FIG. 2B shows a cross-sectional view of a substrate support 250 that includes the heater array 200. The substrate support 250 comprises a baseplate 252 and a ceramic plate 260. For example, the baseplate 252 is made of a metal such as aluminum. The baseplate 252 is similar to the baseplates 32 and 112 shown in FIGS. 1A and 1B. The ceramic plate 260 is similar to the ceramic plates 33 and 114 shown in FIGS. 1A and 1B. A thermal resistance layer 262 (similar to elements 36 and 116 shown in FIGS. 1A and 1B) may be arranged between the ceramic plate 260 and the baseplate 252. The baseplate 252 includes a cooling system 254 similar to the cooling systems 38 and 118 shown in FIGS. 1A and 1B.

The ceramic plate 260 includes several stacked layers of a ceramic material. A clamping electrode 270 is disposed in a first layer 272, which is the top layer on which a substrate (e.g., element 34 or 108 shown in FIGS. 1A and 1B) is arranged during processing. The heaters Hxy are arranged in a second layer 274 under the first layer 272. The Y bus lines are disposed in a third layer 276. The X bus lines and the switches (e.g., diodes) Sxy are arranged in a fourth layer 278. The first terminals of the switches Sxy are directly connected to the X bus lines. Vias 280 connect the first terminals of the heaters Hxy directly to the Y bus lines. Vias 282 connect the second terminals of the heaters Hxy to the second terminals of the switches Sxy.

While not shown, one or more additional zone heaters (also called primary heaters) may be arranged in the ceramic plate 260. For example, these heaters can be arranged above the heater array 200 and under the clamping electrode 270 (e.g., in the first layer 272). Alternatively, these heaters can be arranged under the heater array 200 (e.g., in a fifth layer 290 of the ceramic plate 260).

The switches Sxy increase manufacturing complexity, add cost, and have reliability and lifetime issues. Instead, the present disclosure provides a substrate support without the switches Sxy as follows.

FIG. 3A shows a heater array 300 including a plurality of heaters (resistive elements) arranged in a substrate support (e.g., elements 30 and 106 shown in FIGS. 1A and 1B). For example, the heater array 300 comprises five Y bus lines (Y1, Y2, Y3, Y4, and Y5) and five X bus lines (X1, X2, X3, X4, and X5) arranged in the form of a grid in a ceramic plate (e.g., elements 33 and 114 shown in FIGS. 1A and 1B) of the substrate support. Note that while FIG. 3A shows X=Y, X need not be equal to Y, and X and Y can be any integer greater than 1. Alternatively, the heater array 300 can be arranged elsewhere in the substrate support. For example, the heater array 300 may be arranged under or at the bottom of the ceramic plate adjacent to the baseplate (i.e., between the ceramic plate and the baseplate) and so on.

In the embodiment depicted in FIG. 3A, the heater array 300 comprises X*Y (i.e., X multiplied by Y) number of heaters. Each heater in the heater array 300 can be identified by its location along the X and Y bus lines as a heater Hxy, where x and y respectively denote one of the X bus lines and one of the Y bus lines to which the heater Hxy is connected. In some embodiments, the heater array 300 can include less than X*Y number of heaters (i.e., one or more of the heaters Hxy may be absent in the heater array 300). For example, in each row X, the number of heating elements may be less than or equal to Y. Similarly, each row Y may have a number of heating elements that is less than or equal to X.

The heater array 300 includes Y sets of heaters Hxiy1, Hxiy2, and so on that are arranged along Y columns of the heater array 300, where i = 1 to 5. The heater array 300 includes X sets of heaters Hx1yj, Hx2yj, and so on that are arranged along X rows of the heater array 300, where j=1 to 5. Each of the Y sets of heaters is directly connected to one of the Y bus lines of the heater array 300. Each of the X sets of heaters is directly connected to one of the X bus lines of the heater array 300.

Specifically, heaters in a column have first terminals directly connected to the Y bus line in the column and second terminals directly connected to respective X bus lines in the X rows, and heaters in a row have first terminals directly connected to respective Y bus lines in the Y columns and second terminals directly connected the X bus line in the row.

For example, in the Y sets of heaters, the heaters Hxiy1, where i = 1 to 5, have first terminals directly connected to the Y1 bus line and second terminals directly connected to respective X bus lines; the heaters Hxiy2, where i = 1 to 5, have first terminals directly connected to the Y2 bus lines and second terminals directly connected to respective X bus lines; and so on.

In the X sets of heaters, the heaters Hx1yj, where j = 1 to 5, have first terminals directly connected to respective Y bus lines and second terminals directly connected the X1 bus line; the heaters Hx2yj, where j = 1 to 5, have first terminals directly connected to respective Y bus lines and second terminals directly connected the X2 bus line; and so on.

The Y and X bus lines are connected to a controller (e.g., element 64 or 150 shown in FIGS. 1A and 1B, or element 400 shown in FIG. 5). The controller connects one of the Y bus lines to a power supply (e.g., a voltage source) and one of the X bus lines to a reference potential (e.g., ground). Conversely, in some implementations, the controller connects one of the X bus lines to a power supply and one of the Y bus lines to a reference potential (e.g., ground).

FIG. 3B shows a cross-sectional view of a substrate support 350 that includes the heater array 300. The substrate support 350 comprises a baseplate 352 and a ceramic plate 360. For example, the baseplate 352 is made of a metal such as aluminum. The baseplate 352 is similar to the baseplates 32 and 112 shown in FIGS. 1A and 1B. The ceramic plate 360 is similar to the ceramic plates 33 and 114 shown in FIGS. 1A and 1B. A thermal resistance layer 362 (similar to elements 36 and 116 shown in FIGS. 1A and 1B) may be arranged between the ceramic plate 360 and the baseplate 352. The baseplate 352 includes a cooling system 354 similar to the cooling systems 38 and 118 shown in FIGS. 1A and 1B.

The ceramic plate 360 includes several stacked layers of a ceramic material. A clamping electrode 370 is disposed in a first layer 372, which is the top layer on which a substrate (e.g., element 34 or 108 shown in FIGS. 1A and 1B) is arranged during processing. The heaters Hxy are arranged in a second layer 374 under the first layer 372. The Y bus lines are disposed in a third layer 376. The X bus lines are arranged in a fourth layer 378. Vias 380 connect the first terminals of the heaters Hxy directly to the Y bus lines, respectively. Vias 382 connect the second terminals of the heaters Hxy directly to one of the X bus lines.

The second, third, and fourth layers 374, 376, 378 can be arranged in any order. For example, the second layer 374 can be arranged at the bottom of the ceramic plate 360 adjacent to the baseplate 352 (i.e., between the ceramic plate 360 and the baseplate 352). In some implementations, instead of being arranged in the second layer 374 in the ceramic plate 360, the heaters Hxy can be electrically insulated and arranged external to the ceramic plate 360 at the bottom of the ceramic plate 360 adjacent to the baseplate 352 (i.e., between the ceramic plate 360 and the baseplate 352).

FIG. 4 shows one or more additional zone heaters 386 (also called primary heaters) arranged in the ceramic plate 360. For example, these heaters can be arranged above the heater array 300 and under the clamping electrode 370 (e.g., in the first layer 372). Alternatively, these heaters can be arranged under the heater array 300 (e.g., in a fifth layer 390 of the ceramic plate 360).

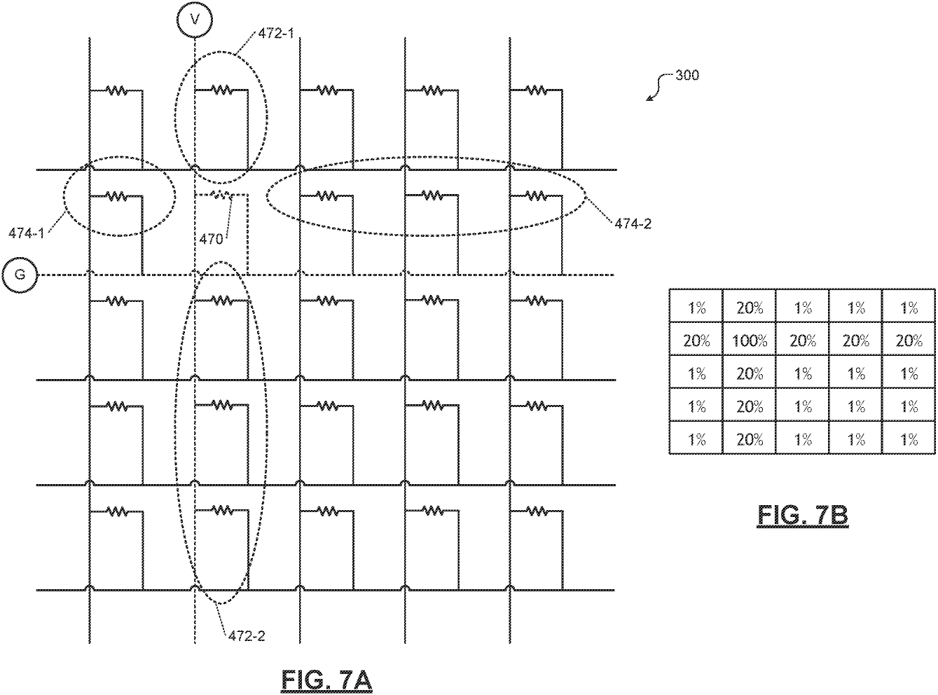

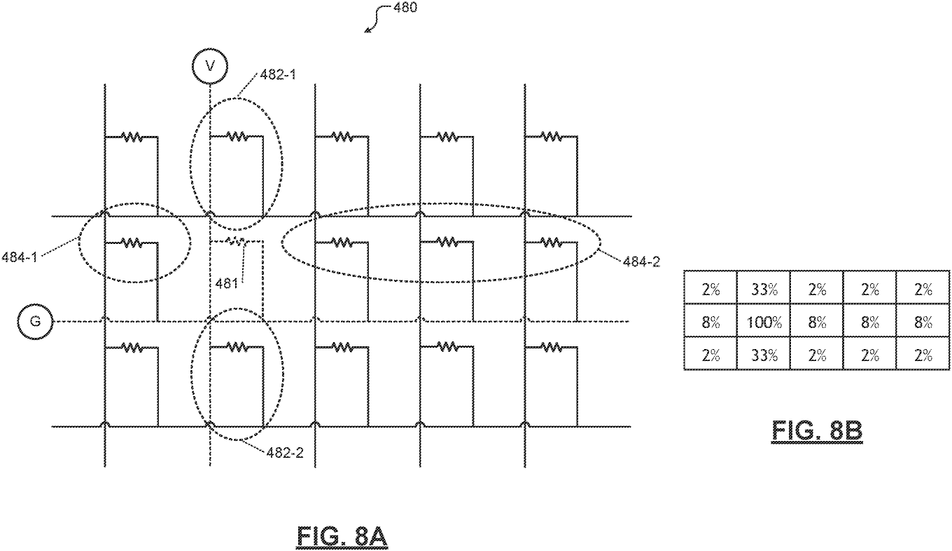

FIG. 5 shows a controller 400 to control the heater array 300. The controller 400 can also control the heater arrays shown in FIGS. 7A and 8A. The controller 400 may be similar to the controllers 64, 70, 150, 160 shown in FIGS. 1A and 1B. The Controller 400 is coupled to a row selector 402 and a column selector 404. In some examples, the row and column selectors 402, 404 may include de-multiplexers. In some examples, the row and column selectors 402, 404 may include decoders. Through the row and column selectors 402, 404, the controller 400 selects only one row (i.e., only one X bus line) and only one column (i.e., only Y bus line) at a time and connects the selected X and Y bus lines respectively to ground and a power supply 406.

The power supply 406 can also supply power to the zone heater 386 shown in FIG. 3B. For example, the power supply 406 can supply DC power. For example, the power supply 406 can comprise a voltage generator that can supply a DC voltage to the heater array 300 and the zone heater 386. For example, the power supply 406 can comprise a voltage generator that can supply a first DC voltage to the heater array 300 and a second DC voltage to the zone heater 386. For example, the power supply 406 can comprise a first voltage generator that can supply a first DC voltage to the heater array 300 and a second voltage generator that can supply a second DC voltage to the zone heater 386.

While the row and column selectors 402, 404 are shown as being external to the controller 400, in some implementations, the controller 400 may include the row and column selectors 402, 404. Further, the controller 400 and the row and column selectors 402, 404 are not implemented in the substrate support 350. Instead, the controller 400 and the row and column selectors 402, 404 are located outside the substrate support 350. The X and Y bus lines from the heater array 300 in the substrate support 350 are connected to the row and column selectors 402, 404 in the controller 400.

FIG. 6A shows an example of heat generated (i.e., the relative power dissipated) by the heater array 300 when one of the X bus lines is connected to ground and one of the Y bus lines is connected to the power supply 406. The selected X and Y bus lines (i.e., those connected to ground and the power supply 406) are shown by dotted lines, and the unselected X and Y bus lines (i.e., those not connected to ground and the power supply 406) are shown by solid lines. The heater 450 at the intersection of the selected X and Y bus lines is shown by dotted lines. The heater 450 generates maximum heat relative to other heaters in the heater array 300.

The heaters other than the heater 450 at the intersection of the selected X and Y bus lines that are also connected to the selected X and Y bus lines are shown by four dotted ovals 452-1 and 452-1 (collectively called the heaters 452) and 454-1 and 454-2 (collectively called the heaters 454). Additional other heaters in the heater array 300 are identified by dotted ovals 460-1, 460-2, 460-3, and 460-4 (collectively heaters 460), and by dotted ovals 462-1, 462-2, 462-3, and 462-4 (collectively heaters 462).

FIGS. 6B, 6C, and 6D show some of a number of examples of additional current paths in the heater array 300 due to the direct connections of the heaters to the X and Y bus lines in the heater array 300. These current paths are in addition to the main current path via which current flows through the heater 450 as shown in FIG. 6A.

For example, in FIGS. 6B and 6D, a three-heater current path that includes one heater from the heaters 460 also includes one heater from the heaters 452 and one heater from the heaters 454. In FIG. 6C, a three-heater current path that includes one heater from the heaters 462 also includes one heater from the heaters 452 and one heater from the heaters 454 but does not include any heater from the heaters 460.

Due to these current paths, the heat generated by the heaters 460 and 462 is approximately the same. The heat generated by the heaters 452 and 454 is greater than the heat generated by the heaters 460 and 462 and is less than the heat generated by the heater 450.

FIG. 6E shows the relative amount of heat generated by the heaters in the heater array 300 relative to and as a percentage of the heat generated by the selected heater, which in this example is the heater 450, and the heat from which is maximum or 100%. The percentages represent the relative power of the other heaters in the heater array 300 relative to the selected heater 450.

For example, FIG. 6E shows that when selected by the X and Y bus lines as shown in FIG. 6A, the heater 450 at the intersection of the selected by the X and Y bus lines generates the maximum or 100% of the heat. The other heaters 452, 454 that are also directly connected to the selected by the X and Y bus lines but are not at the intersection of the selected by the X and Y bus lines generate a smaller amount of heat than the heater 450. The heaters 460, 462 that are not directly connected to the selected by the X and Y bus lines generate a still smaller amount of heat than the heaters 452, 454.

As shown in the example in FIGS. 6A and 6E, every heater in the heater array 300 is at full power (100%) once, at 20% of the full power 8 times, at 1% of the full power 16 times in one cycle. For example, in one cycle, the controller 400 can select and connect different pairs of the X and Y bus lines (25 pairs in the 5x5 example), one pair at a time, to the power supply 406 and ground in a sequence. The sequence and the amount of time for which a pair of X and Y bus line is connected to the power supply 406 and ground depend on a desired temperature profile for processing a substrate. In some examples, a cycle may not include selecting all 25 pair combinations, and the controller 400 may skip selecting some of the 25 pair combinations depending on the desired temperature profile. In some examples, a first cycle may include a first set of the 25 pair combinations, which may be followed by a second cycle including a different set of the 25 pair combinations. Various other sequences are contemplated.

FIGS. 7A and 7B show another example, where a different heater 470 in the heater array 300 than the heater 450 is selected by selecting a different pair of X and Y bus lines of the heater array 300. FIG. 7B shows the relative amount of heat generated by the heaters in the heater array 300 relative to the selected heater 470, where the percentages represent the relative power of the other heaters relative to the selected heater 470.

For example, FIG. 7B shows that when selected by the X and Y bus lines as shown in FIG. 7A, the heater 470 at the intersection of the selected by the X and Y bus lines generates the maximum or 100% of the heat. The other heaters 472-1, 472-2 (collectively heaters 472) and 474-1, 474-2 (collectively heaters 474) that are also directly connected to the selected by the X and Y bus lines but are not at the intersection of the selected by the X and Y bus lines generate a smaller amount of heat than the heater 450. All other heaters other than the heaters 470, 472, and 474 that are not directly connected to the selected by the X and Y bus lines generate a still smaller amount of heat than the heaters 472, 474.

FIGS. 8A and 8B show another configuration of a heater array with fewer heaters than the heater array 300. For example, FIG. 8A shows a 5x3 heater array 480 instead of a 5x5 heater array 300 shown in FIGS. 6A-7A. FIG. 8B shows the relative amount of heat generated by the heaters in the heater array 480 relative to a selected heater 481, which is shown by dotted lines. The percentages also represent the relative power of the heaters relative to the selected heater 481, which generates maximum amount of heat (shown as 100%).

In FIG. 8A, fewer heaters 482-1, 482-2 (collectively heaters 482) are connected to the selected Y bus line than the number of heaters 484-1, 484-2 (collectively heaters 484) connected to the selected X bus line. FIG. 8B shows that the smaller number of heaters 482 on the selected Y bus line generate a higher amount of heat than the heaters 484 on the selected X bus, and the heaters 482, 484 generate greater heat than the heaters on the non-selected X and Y bus lines in the heater array 480.

Accordingly, heater arrays having different number of heaters, different number of bus lines, and different configurations can be implemented in substrate supports depending on application and temperature profile requirements. For example, in some implementations, a heater array (e.g., the heater array 300, 480) including X and Y bus lines need not include X*Y heaters; rather a heater array can include less than or equal to X*Y heaters. Regardless of the number of heaters, the number of bus lines, and the configurations of the heater arrays, the controller 400 can control the heaters in the heater arrays in various sequences as described above to generate desired temperature profiles for processing substrates.

FIG. 9 shows a method 500 of controlling a heater array during processing of a substrate according to the present disclosure. For example, 64, 70, 150, 160 shown in FIGS. 1A and 1B and/or the controller 400 shown in FIG. 5 can perform the method 500 to control the heater arrays 300, 480.

At 502, the method 500 receives a sequence in which to energize the heaters in the heater array to process the substrate. That is, the sequence may include an order in which to select X and Y bus lines of the heater array and supply power to the selected X and Y bus lines of the heater array. For example, the sequence may be based on a desired temperature profile for the substrate being processed. At 504, the method 500 selects a first row and a first column of heaters (i.e., first X and Y bus lines) in the heater array according to the sequence. At 506, the method 500 connects the selected row and column of heaters (i.e., first X and Y bus lines) across a reference potential and a voltage source (e.g., applies a DC voltage across the heaters in the first X and Y bus lines of the selected row and column of heaters).

At 508, the method 500 determines if a predetermined amount of time has elapsed. That is, the method 500 applies the DC voltage across the heaters in the selected X and Y bus lines for the predetermined amount of time. The predetermined amount of time is selected based on the data associated with the sequence. The predetermined amount of time may be the same throughout the method 500 (i.e., for all sequence steps) or may vary each time steps 504, 506, and 508 are performed by the method 500. The method 500 proceeds to step 510 after the predetermined amount of time has elapsed.

At 510, the method 500 determines if the sequence is completed. The method 500 proceeds to step 512 if the sequence is not completed and proceeds to step 516 if the sequence is completed. At 510, the method 500 disconnects the selected row and/or column of heaters (i.e., the selected X and/or Y bus lines) from the reference potential and/or the voltage source, respectively. At 514, the method 500 selects a next row and/or a next column of heaters (i.e., a next X and/or Y bus lines) in the heater array according to the sequence and connects the selected row and/or column of heaters across the reference potential and the voltage source (e.g., applies a DC voltage across the next X and/or Y bus lines of the selected row and/or column of heaters). The method 500 returns to step 508.

At 510, if the method 500 determines that the sequence is completed, the method 500 proceeds to step 516. At 516, the method 500 determines whether to repeat the same sequence or to obtain a new sequence in which to energize the heaters in the heater array for subsequent processing of the substrate. Alternatively, the method 500 can also end after completing the sequence. The method 500 returns to step 504 if the same sequence is to be repeated. The method 500 returns to step 502 if a new sequence is to be obtained for subsequent processing of the substrate.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support assembly for supporting a substrate, the substrate support assembly comprising:
a baseplate;
a ceramic plate arranged on the baseplate, the ceramic plate including:
Y conductors arranged in a first layer of the ceramic plate; and
X conductors arranged in a second layer of the ceramic plate; and
N resistive heaters arranged in X rows and Y columns and coupled to the ceramic plate, where X, Y, and N are integers greater than 1, and N is less than or equal to X*Y, each of the N resistive heaters having a first terminal and a second terminal;
wherein first terminals of each resistive heater in one of the X rows are directly connected to the Y conductors, respectively, by first vias; and
wherein second terminals of each resistive heater in the one of the X rows are directly connected to one of the X conductors by second vias.

2. The substrate support assembly of claim 1 wherein the N resistive heaters are electrically insulated from the baseplate and are arranged at the bottom of the ceramic plate between the baseplate and the ceramic plate.

3. The substrate support assembly of claim 1 wherein the N resistive heaters are arranged in a third layer of the ceramic plate.

4. The substrate support assembly of claim 1 further comprising a controller configured to:
connect one of the Y conductors to a power supply; and
connect one of the X conductors to a reference potential.

5. The substrate support assembly of claim 1 further comprising a controller configured to connect the Y conductors to a power supply and the X conductors to a reference potential in a sequence by connecting one of the Y conductors to the power supply and connecting one of the X conductors to the reference potential at a time.

6. The substrate support assembly of claim 5 wherein the sequence is based on a temperature profile for processing the substrate.

7. The substrate support assembly of claim 1 further comprising a controller configured to:
connect a first one of the Y conductors to a power supply for a first time period;
connect a first one of the X conductors to a reference potential for the first time period;
disconnect the first one of the Y conductors from the power supply after the first time period; and
connect a second one of the Y conductors to the power supply for a second time period.

8. The substrate support assembly of claim 1 further comprising a controller configured to:
connect a first one of the Y conductors to a power supply for a first time period;
connect a first one of the X conductors to a reference potential for the first time period;
disconnect the first one of the X conductors from the reference potential after the first time period; and
connect a second one of the X conductors to the reference potential for a second time period.

9. The substrate support assembly of claim 1 further comprising a controller configured to:
connect a first one of the Y conductors to a power supply for a first time period;
connect a first one of the X conductors to a reference potential for the first time period;
disconnect the first one of the Y conductors from the power supply after the first time period;
disconnect the first one of the X conductors from the reference potential after the first time period;
connect a second one of the Y conductors to the power supply for a second time period; and
connect a second one of the X conductors to the reference potential for the second time period.

10. The substrate support assembly of claim 1 wherein the second layer is adjacent to the baseplate, and the first layer is arranged on the second layer.

11. The substrate support assembly of claim 3 wherein the second layer is adjacent to the baseplate, the first layer is arranged on the second layer, and the third layer is arranged on the first layer.

12. The substrate support assembly of claim 3 wherein the first, second, and third layers are arranged in any order.

13. The substrate support assembly of claim 1 further comprising one or more additional heaters arranged in a third layer of the ceramic plate, wherein the third layer is arranged above or below the first and second layers.

14. The substrate support assembly of claim 3 further comprising one or more additional heaters arranged in a fourth layer of the ceramic plate, wherein the fourth layer is arranged above or below the first, second, and third layers.

15. The substrate support assembly of claim 1 further comprising a clamping electrode and one or more additional heaters arranged in a third layer of the ceramic plate, wherein the third layer is arranged above the first and second layers.

16. The substrate support assembly of claim 1 further comprising:
a clamping electrode arranged in a third layer of the ceramic plate, wherein the third layer is arranged above the first and second layers; and
one or more additional heaters arranged in a fourth layer of the ceramic plate, wherein the fourth layer is arranged below the first and second layers.

17. The substrate support assembly of claim 3 further comprising a clamping electrode and one or more additional heaters arranged in a fourth layer of the ceramic plate, wherein the fourth layer is arranged above the first, second, and third layers.

18. The substrate support assembly of claim 3 further comprising:
a clamping electrode arranged in a fourth layer of the ceramic plate, wherein the fourth layer is arranged above the first, second, and third layers; and
one or more additional heaters arranged in a fifth layer of the ceramic plate, wherein the fifth layer is arranged below the first, second, and third layers.

19. The substrate support assembly of claim 1 further comprising an adhesive layer arranged between the baseplate and the ceramic plate.

20. The substrate support assembly of claim 1 wherein the baseplate includes channels for flowing a coolant through the baseplate.

21. A system comprising:
the substrate support assembly of claim 1;
a power supply configured to supply a first DC voltage; and
a controller configured to sequentially apply the first DC voltage across the X and Y conductors by connecting one pair of the X and Y conductors at a time to the power supply and a reference potential.

22. The system of claim 21 wherein a sequence for sequentially applying the first DC voltage across the X and Y conductors is based on a temperature profile for processing the substrate.

23. The system of claim 21 wherein:
the substrate support assembly further comprises one or more additional heaters arranged in a third layer of the ceramic plate, wherein the third layer is arranged above or below the first and second layers;
the power supply is configured to supply a second DC voltage; and
the controller is configured to supply the second DC voltage to the one or more additional heaters.

24. A system comprising:
the substrate support assembly of claim 3;
a power supply configured to supply a first DC voltage; and
a controller configured to sequentially apply the first DC voltage across the X and Y conductors by connecting one pair of the X and Y conductors at a time to the power supply and a reference potential.

25. The system of claim 24 wherein a sequence for sequentially applying the first DC voltage across the X and Y conductors is based on a temperature profile for processing the substrate.

26. The system of claim 24 wherein:
the substrate support assembly further comprises one or more additional heaters arranged in a fourth layer of the ceramic plate, wherein the fourth layer is arranged above or below the first, second, and third layers;
the power supply is configured to supply a second DC voltage; and
the controller is configured to supply the second DC voltage to the one or more additional heaters.
